(19) United States
(12) Patent Application Publication
(10) Pub. No.: US 2006/0030138 A1
(43) Pub. Date: Feb. 9, 2006

(54) Layout method for semiconductor integrated circuit device

(75) Inventor: Masashi Konishi, Takatsuki-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/197,307

(22) Filed: Aug. 5, 2005

(30) Foreign Application Priority Data
Aug. 9, 2004 (JP) 2004-232530

(51) Int. Cl. H01L 21/44; H01L 27/10; H01L 21/3205

(52) U.S. Cl. 438/599; 257/208; 257/210; 438/589; 257/203

(57) ABSTRACT

Provided is a layout method for a semiconductor integrated circuit device in which area pads and peripheral wiring patterns thereof can be automatically laid out. At least one of a plurality of cells are made area pad cells, at least one of the remaining cells are made wiring pattern cells, and then the area pad cells and the wiring pattern cells are stored in a design library. Arrangement positions of the area pad cells and the wiring pattern cells are calculated based on the design library and prepared arrangement information or wiring structure information on both cells and then both cells are arranged automatically. As a result, a layout design to satisfy design rules can be prepared while securing connections between the cells and between the cells and other wiring patterns through the use of pins and contacts at boundary portions of the cells and intra-cell wiring portions. And at the same time, a layout database having information on all of the layout is created by conducting a conventional automatic layout.

### BACKGROUND OF THE INVENTION

1. Field of the Invention

The present invention relates to a layout method for a semiconductor integrated circuit device.

2. Background Art

As semiconductor integrated circuit devices become smaller in size and have higher degrees of integration, the tendencies for integrated circuits to become more complicated and for input-output pads to increase in number are accelerated more and more but at the same time, there is a necessity to implement the minimization of chip areas. To minimize the chip areas, a method of arranging the input-output pads at not only the periphery of the chip but also the center of the chip is effective; hence, such pads are called area pads. Generally, the area pads are used often for power supply to the inside of the chip and in those cases, the area pads and the inside of the chip are connected often by a metal wiring having a strap structure, a mesh structure, or the like.

In conventional layout methods for a semiconductor integrated circuit device, the area pads and their periphery wiring patterns are manually produced by using the editing function of an automatic layout tool and a manual editing tool having a higher degree of editing function (see JP-A No. 2003-100891). For instance, in a relatively simple case, the area pads and their periphery wiring patterns are produced by using the editing function of the automatic layout tool. And furthermore, in a more complicated case, various layout analyses and layout verifications are conducted by transferring layout information on the area pads and their periphery wiring patterns produced using the manual editing tool and layout information on other cells and wiring patterns produced using the automatic layout tool to either tool or by unifying both pieces of layout information through the use of another mask process tool or the like.

As for the conventional layout method for a semiconductor integrated circuit device, it is impossible to automatically lay out the area pads and their peripheral wiring patterns. This is because the area pads and their peripheral wiring patterns are unsuitable for the conventional automatic layout since not only it is difficult to produce the complex shaped area pads and the peripheral wiring patterns in complex form but there is a necessity to systematically arrange the pads and to systematically produce the patterns both according to a specific method.

In addition, when area pads, their peripheral wiring patterns, and so on produced using other manual editing tools are unified with other cells, wiring patterns, and so on produced using the automatic layout tool, the omission of layout information such as arrangement-wiring history information is inevitable, which makes a database imperfect.

### SUMMARY OF THE INVENTION

An object of the present invention is to provide a layout method for a semiconductor integrated circuit device in which area pads and their peripheral wiring pattern can be laid out automatically.

To attain such an object, a layout method for a semiconductor integrated circuit device according to a first invention is devised as a layout method for a semiconductor integrated circuit device in which the area pads and their periphery wiring pattern are laid out by using a design library having information on a plurality of cells; therefore, this layout method includes steps of making at least one of the cells wiring pattern cells, storing the wiring pattern cells in the design library, calculating arrangement positions of the wiring pattern cells based on the design library and prepared arrangement information or wiring structure information on the cells, and automatically arranging the wiring pattern cells.

According to such a configuration, a layout design to satisfy design rules can be prepared while securing connections between the cells and between the cells and other wiring patterns through the use of pins and contacts at boundary portions of the cells and intra-cell wiring portions. And at the same time, a layout database including all the layout information is created by conducting a conventional automatic layout; as a result, it is possible to implement automation of the layout of the peripheral wiring patterns. In addition, wiring patterns in arbitrary form can be used and the degree of freedom in the layout is increased.

A layout method for a semiconductor integrated circuit device according to a second invention includes steps of producing as area pad cells at least one of the cells other than the cells prepared according to the first invention as the wiring pattern cells, storing the area pad cells in the design library, calculating arrangement positions of the area pad cells based on the design library and prepared arrangement information or wiring structure information on the area pad cells, and automatically arranging the area pad cells.

By adopting such a configuration, automation of the layout of the area pad cells and their peripheral wiring pattern can be implemented. Besides, arbitrary shaped area pads and wiring patterns in arbitrary form can be used and the degree of freedom of the layout is increased. Furthermore, the layout verifications such as checks on design rules and LVS and the layout analyses of RC extraction, delay calculation, crosstalk, electromigration, power supply voltage drop, base noise, and so on can be conducted by producing the layout database having all the layout information on transistor layers through uppermost wiring layers including the area pads.

A layout method for a semiconductor integrated circuit device according to a third invention corresponds to the layout method for a semiconductor integrated circuit device according to the second invention in which the area pads cells and the wiring pattern cells have connecting pins at their boundary portions.

According to such a configuration, since the area pad cells and the wiring pattern cells have the connecting pins at their boundary portions, the adjacent arrangement of the area pad cells and the wiring pattern cells simply allows an automatic layout tool to recognize their mutual connection, so that no wiring is required between the cells.

### BRIEF DESCRIPTION OF THE DRAWINGS

FIG. 1 is a diagram showing examples of area pad cells and wiring pattern cells produced according to an embodiment of the present invention,

FIG. 2 is a diagram showing an exemplary arrangement of the wiring pattern cells according to the embodiment of the invention,

FIG. 3 is a diagram showing an exemplary arrangement of the area pad cells and the wiring pattern cells according to the embodiment of the invention,

FIG. 4 is a flowchart showing the calculation of optimum arrangement positions of the area pad cells and the wiring pattern cells based on the arrangement information thereof and the automatic arrangement thereof according to the embodiment of the invention, and

FIG. 5 is a flowchart showing the calculation of optimum arrangement positions of the area pad cells and the wiring pattern cells based on the wiring structure information thereof and the automatic arrangement thereof according to the embodiment of the invention.

### DESCRIPTION OF THE EXEMPLARY EMBODIMENT

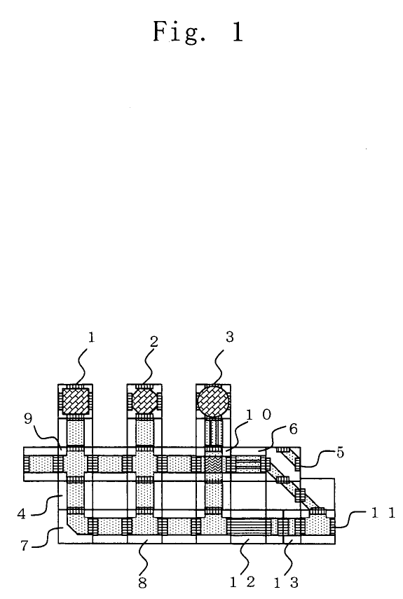

An embodiment according to the present invention will be described with reference to FIGS. 1 to 5. FIG. 1 is a diagram showing examples of area pad cells and wiring pattern cells produced according to the embodiment of the invention.

With the area pad cells, as shown in FIG. 1, it is possible to produce cells having arbitrary shaped pads and wiring in arbitrary form such as the cell 1 having a square pad, the cell 2 having an octagonal pad, and the cell 3 having a circular pad. Also, with the wiring pattern cells, it is possible to produce cells having arbitrary wiring patterns such as the straight-line wiring cell 4, the oblique wiring cell 5, the slit wiring cell 6, the L-shaped joint cell 7, the T-shaped joint cell 8, the cross joint cell 9, and the contact cell 10 connected to other wiring layers.

In producing these area pad cells and wiring pattern cells, to make it possible to place them onto arbitrary locations, they are given cell properties which allow overlapping with other cells and wiring patterns such as standard logic cells, macrocells, and functional blocks. Besides, by adopting a configuration in which connecting pins 11 are provided to the boundaries between the area pad cells and the wiring pattern cells, it becomes possible for automatic layout tools to mutually recognize their connection in a state in which these cells are simply arranged, so that no wiring is required between the cells. Furthermore, by adopting a configuration in which connecting pins 12 are provided to wiring portions in the area pad cells and the wiring pattern cells, conventional wiring pattern cells, pad cells, and wiring pattern traces in the wiring pattern cells can be connected to arbitrary places in the cells, so that degrees of freedom in the automatic arrangement of the cells and the later correction of the arrangement using the conventional wiring pattern can be improved. In addition, there is no need for these cells to be of the same size; hence by using, for example, the wiring pattern cells having several different sizes, such as a cell 13 whose side is half those of the other cells in length, the degree of freedom of the wiring pattern produced can be improved as well.

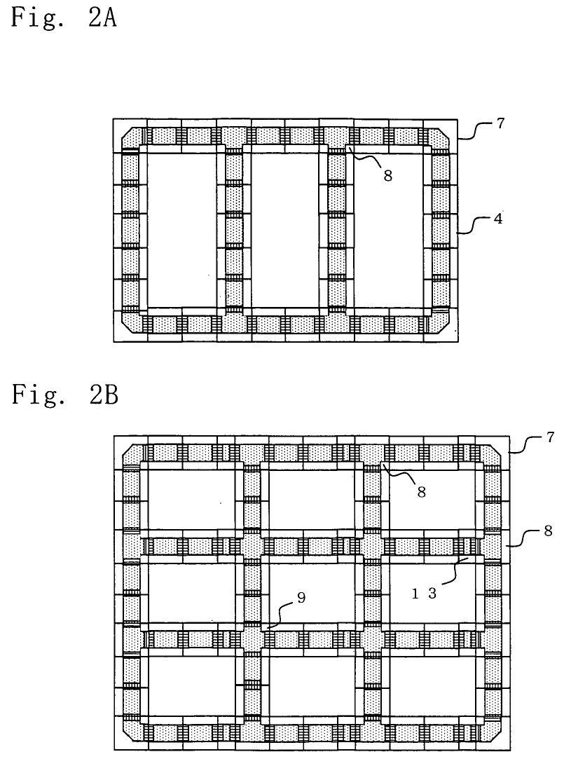

FIG. 2 is a diagram showing an exemplary arrangement of the wiring pattern cells according to the embodiment of the invention. By arranging the straight-line wiring cells 4, the L-shaped joint cells 7, and the T-shaped joint cells 8 as shown in FIG. 2A, a strap wiring structure is built. Moreover, by arranging the cells 4, 7, and 8 in combination with the different size wiring cells 13 and the cross joint cells 9 as shown in FIG. 2B, a mesh wiring structure having arbitrary wiring spacings independent of the cell sizes is built. Here, by arranging those cells in combination with the slit wiring cells 6 shown in FIG. 1, a wiring structure is built in which design rules including a maximum wiring width constraint, a special spacing constraint of thick wiring, and so on are satisfied. Furthermore, by arranging those cells in combination with wiring pattern cells having arbitrary complex shapes such as the oblique wiring cells 5, a more complex wiring structure is built.

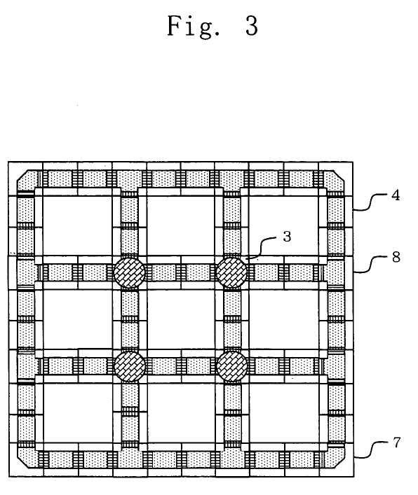

FIG. 3 is a diagram showing an exemplary arrangement of the area pad cells and the wiring pattern cells according to the embodiment of the invention. By arranging the area pad cells 3, the wiring pattern cells 4, and the joint cells 7 and 8 as shown in FIG. 3, a wiring structure including the area pads is built. Here, by arranging those cells in combination with the oblique wiring cells 5, the slit wiring cells 6, the different size wiring cells 13, etc. shown in FIG. 1, an arbitrary complex wiring structure including the area pads, which satisfies design rules, is built.

As methods for automatically conducting the arrangement shown in FIGS. 2 and 3, the following methods are conceivable: to begin with, there is a method of calculating the optimum arrangement positions of the area pad cells and the wiring pattern cells based on arrangement information and automatically arranging them and then there is a method of calculating the optimum arrangement positions of the area pad cells and the wiring pattern cells based on wiring structure information and automatically arranging them. At this time, at least one of a plurality of cells are made the area pad cells, at least one of the remaining cells are made the wiring pattern cells, the area pad cells and the wiring pattern cells are stored in the design library, the arrangement positions of the area pad cells and the wiring pattern cells are calculated based on this design library and the prepared arrangement information or wiring structure information on cells, and the both cells are arranged automatically. In the following, these methods will be described in detail.

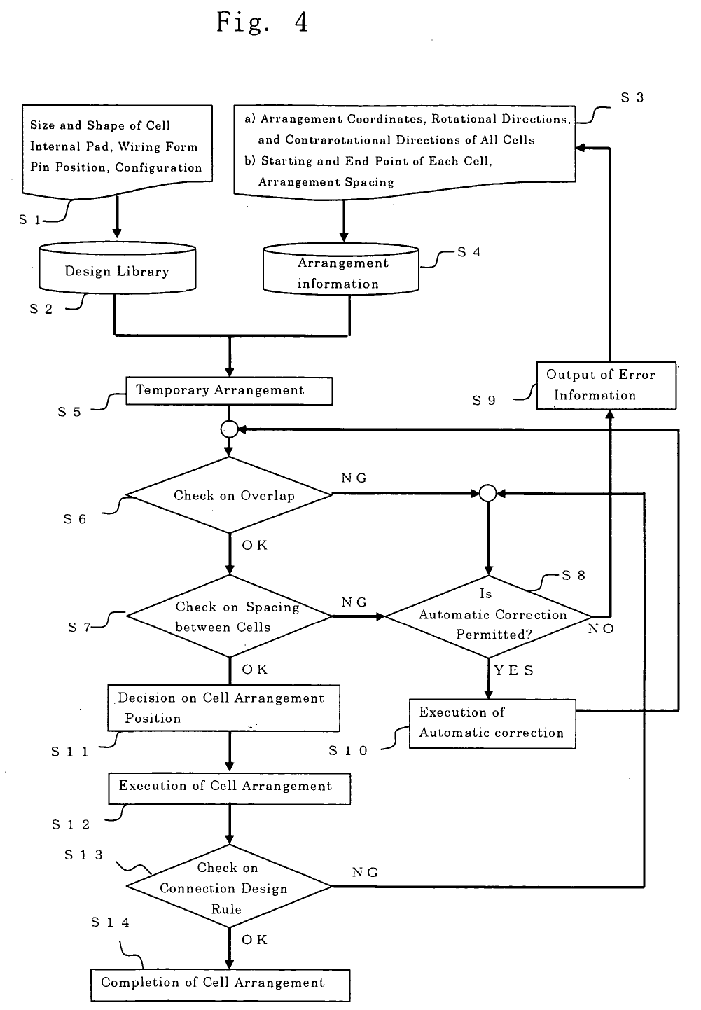

FIG. 4 is a flow chart showing the calculation of the optimum arrangement positions of the area pad cells and the wiring pattern cells based on the arrangement information and the automatic arrangement thereof according to the embodiment of the invention. As shown in FIG. 4, information on the size and shape of all the area pad cells and wiring pattern cell, the pads and wiring form inside the cells, the positions of the pins, the configuration and connect directions of the cells, etc. is prepared (Step S1) and then a design library having these pieces of information is made (Step S2). And at the same time, as the arrangement information, the arrangement coordinates, rotational directions, and contrarotational directions of all the cells are prepared (Step S3a) or the coordinates of the starting point and endpoint of each cell's arrangement region and the arrangement spacing between the cells are prepared (Step S3b) to generate the arrangement information (Step S4). Then the area pad cells and the wiring pattern cells are temporarily arranged based on the design library and the arrangement information (Step S5), after which the check on the overlaps between the cells is conducted (Step S6), the check on the gaps between the cells is conducted (Step S7), and a confirmation that all of the temporarily arranged cells are adjacently arranged without leaving gaps is made. When some problem has been found during these steps, it becomes necessary to correct the arrangement information; however, when automatic correction is not permitted at Step S8, a need to regenerate the arrangement information arises based on the types of errors, places of their occurrence, and the cells at which the errors have occurred outputted at Step S9 and several proposed automatic corrections. When the automatic correction is permitted at Step S8, the automatic correction is made according to the following procedure at Step S10. To begin with, with the errors concerning overlaps between the cells, when the cells completely lie one upon another, priorities are previously assigned to the area pad cells, the joint cells, special wiring cells, and regular wiring cells in that order, so the cell with the lower priority is removed. Naturally, by arbitrarily changing these priorities, it is also possible to control the cells to be left. Moreover, when the adjacent cells overlap each other, their overlap is avoided by replacing part of the wiring cells with the different-size cell or by displacing the adjacent cells one after the other. As for such an automatic correction, when there is a possibility of several automatic corrections, provision for the selection of a desired automatic correction procedure from the several proposed automatic corrections can be made (Step S10). Besides, these proposed automatic corrections are also utilized as part of the error information outputted at Step S9 when the automatic correction is not permitted at Step S8. As a consequence, only when checks on the overlap and the spacing between the cells have been OKed and the automatic correction has been conducted at Step S10, the arrangement information on all the cells is determined (Step S11) and then all the cells are automatically arranged besed on this arrangement information (Step S12). At a point in time when the automatic arrangement of all the cells has been completed, checks on their connections and design rules are conducted (Step S13). When these checks are not OKed, the automatic correction is executed again at Step S8 or the arrangement information is regenerated based on outputted error information. As a result of this, when the checks are OKed, the arrangement of the cells is determined to be a final cell arrangement; thus the automatic arrangement of the area pad cells and the wiring pattern cells is completed (Step S14).

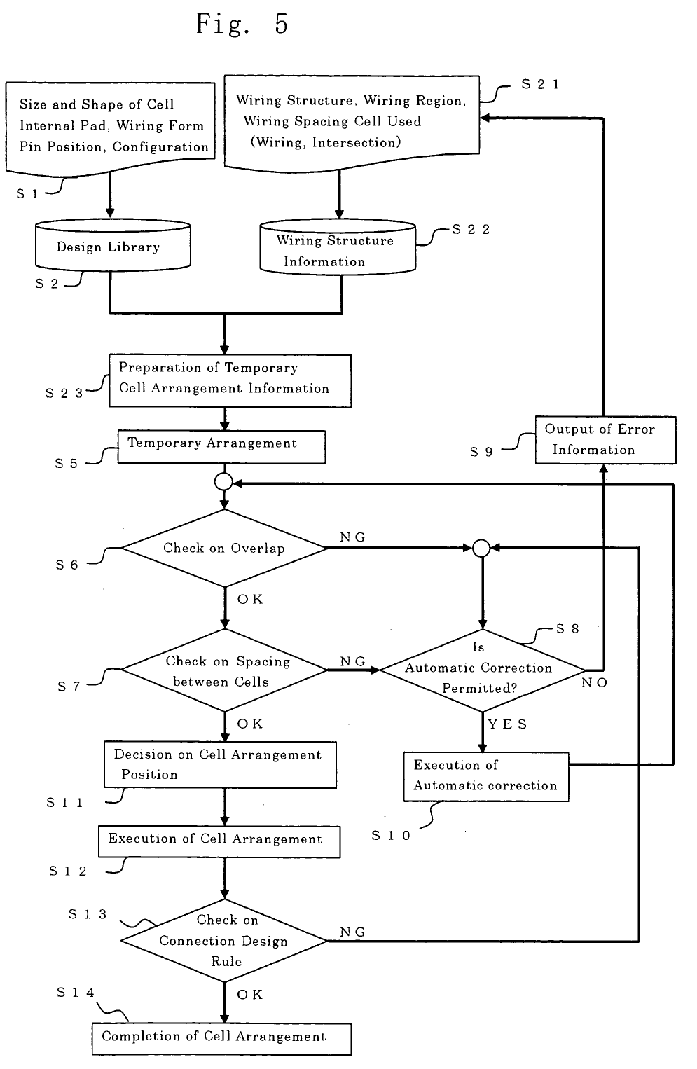

FIG. 5 is a flow chart showing the calculation of optimum arrangement positions of the area pad cells and the wiring pattern cells based on the wiring structure information and the automatic arrangement of the cells according to the embodiment of the invention. Differences between the flow shown in FIG. 5 and the flow shown in FIG. 4, in which the automatic arrangement is conducted based on the arrangement information, will be described below. As shown in FIG. 5, in this flow, wiring structure information is prepared as initial information instead of the arrangement information (Step S21). Examples of the wiring structure information includes the wiring structures such as the strap structure and the mesh structure, wiring spacings, regions at which the wiring structures are built, and the names of the area pad cells, the wiring pattern cells and the joint cells used for the wiring and intersections. The necessary cells are selected from the design library (Step S2) based on the wiring structure information (Step S22) and temporary arrangement information is generated to satisfy the wiring structure (Step S23). When the temporary arrangement information on the cells has been generated from the wiring structure information in this way, the subsequent flow becomes the same as that shown in FIG. 4 in which the automatic arrangement is conducted based on the arrangement information.

Next, consideration is given to the application of the wiring structure according to this embodiment to an actual layout design. To begin with, it is also conceivable that the actual layout design does not include even arrangement wiring structure but includes more complicated arrangement wiring structure. For instance, there are cases where a strap structure is partly present in a mesh structure, a wiring structure is not present only in certain areas, and no fixed wiring structure is present. In FIGS. 2 and 3, the fixed wiring structures including the area pad cells and the wiring pattern cells have been indicated; therefore, by using the automatic arrangement method for the area pad cells and the wiring pattern cells, any wiring structure can be built. Concretely, by specifying the coordinates of all the area pad cells and wiring pattern cells, by building a wiring construction through the designation of some area, or by replacing part of a wiring structure which has been once built, it is possible to make an automatic arrangement for a complicated arrangement wiring structure.

Besides, in the actual layout design, there may be a necessity to correct the arrangement of the area pad cells and the wiring pattern cells because of the modifications of requirements, circuits, or the like. Even in such a case, the shape of the pad, the shape of the wiring, the width of the wiring, and the like can be corrected easily by replacing the area pad cells and the wiring pattern cells.

As the handling of layout design data, it is desirable that the data on the area pad cells and the wiring pattern cells, which is generated according to the flows shown in FIGS. 2 and 3, can be handled on the same database as that of the arrangement-wiring data on conventional cells and wiring patterns. For example, when a conventional automatic layout tool is provided with the functions of arranging and wiring area pad cells and wiring pattern cells, all layout data on transistor layers through wiring layers and area pad layers can be generated on the automatic layout tool by using the same design database.

Furthermore, when a recent multifunction integrated layout tool is provided with the functions of arranging and wiring area pad cells and wiring pattern cells, it becomes possible to not only generate all the layout data but conduct their layout verifications and layout analyses. Specifically, it becomes possible to conduct the layout verifications such as checks on design rules and LVS and the layout analyses of RC extraction, delay calculation, crosstalk, electromigration, the amount of power supply voltage drop, base noise, and so on.

1. A layout method for a semiconductor integrated circuit device using a design library having information on a plurality of cells, wherein
at least one of the cells are made wiring pattern cells,
the wiring pattern cells are stored in the design library,
arrangement positions of the wiring pattern cells are calculated based on the design library and prepared arrangement information or wiring structure information on the wiring pattern cells, and
the wiring pattern cells are arranged automatically.

2. The layout method for a semiconductor integrated circuit device according to claim 1, wherein
at least one of the cells other than the cells produced as the wiring pattern cells are made area pad cells,
the area pad cells are stored in the design library,
arrangement positions of the area pad cells are calculated based on the design library and prepared arrangement information or wiring structure information on the area pad cells, and
the area pad cells are arranged automatically.

3. The layout method for a semiconductor integrated circuit device according to claim 2, wherein the area pad cells and the wiring pattern cells have connecting pins at the boundary portions thereof.
